(19) United States
(12) Patent Application Publication
(10) Pub. No.: US 2002/0023248 A1
(43) Pub. Date: Feb. 21, 2002

(54) Medium defect detection method and data storage apparatus

(75) Inventors: Tomohiro Suzuki, Kawasaki (JP); Kaneyasu Shimoda, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED

(21) Appl. No.: 09/764,385

(22) Filed: Jan. 19, 2001

(30) Foreign Application Priority Data
Jun. 6, 2000 (JP) 2000-169437

(51) Int. Cl. G11C 29/00

(52) U.S. Cl. 714/764

(57) ABSTRACT

In a medium defect detection method of the invention, a data storage apparatus selectively operable for one of a normal data reading and a medium defect detection is provided, the data storage apparatus providing an ability to correct an error in readout information during the normal data reading. A sequence of data frames is written to a storage medium. The data frame sequence is read from the medium by producing a readout signal. It is determined whether an error occurs in the readout signal. The writing, reading and determining steps are performed during the medium defect detection by inhibiting the error correction ability of the data storage apparatus. In a data storage apparatus of the invention, a read/write unit writes a sequence of data frames to the medium and reads the sequence of data frames from the medium by producing a readout signal. A detector, selectively operable for one of a normal data reading and a medium defect detection, the detector performing a maximum likelihood sequence detection of the readout signal, providing an ability to correct an error in the readout signal. The detector performs an error detection of the readout signal. A control unit controls the detector to perform selected one of the sequence detection and the error detection, wherein, when the error detection is selected, the control unit reduces the error correction ability of the sequence detection.

### BACKGROUND OF THE INVENTION

1. Field of the Invention

The present invention generally relates to a medium defect detection method and a data storage apparatus, and more particularly to a medium defect detection method that detects a defect in a storage medium on a data storage apparatus wherein the maximum likelihood sequence detection has the ability of error correction, as well as to the data storage apparatus using the medium defect detection method.

2. Description of the Related Art

A data storage apparatus, such as a magnetic disk drive, includes a data reproduction portion employing the maximum likelihood sequence detection, and the maximum likelihood sequence detection is usually provided with the ability of error correction. In recent years, with the achievement of improved data storage capacity, the ability of error correction of the data reproduction portion of the existing data storage apparatus has been improved. Even if a small defect exists on the storage medium, the defect is corrected and the original data is recovered by the error correction ability of the maximum likelihood sequence detection. Hence, as a result of the error correction coding (ECC), the existing data storage apparatus determines that there is no error on the storage medium, even when a small defect actually exists on the storage medium.

Further, with the achievement of improved data storage capacity, the margin of the amplitude of a readout signal that can be detected by the existing data storage apparatus is reduced. The magnetization will be reduced if a defect exists on the storage medium, and the margin of the amplitude of the readout signal from a defective block of the storage medium will be further reduced.

In such circumstances, the existing data storage apparatus irregularly determines whether or not a defect exists on the storage medium, and the results of the medium defect detection will be inadequate for providing good reliability of the detection. It is desirable to provide a medium defect detection method and apparatus that can accurately and reliably detect a small defect on the storage medium.

A description will be provided of a conventional medium defect detection method. When performing the conventional medium defect detection, parity bits are added to a block of binary data as insurance against possible read/write errors, scrambling is performed on the data, and the data is runlength-limited (RLL) coded. The RLL-coded data is written to a given sector of the storage medium.

After the writing is performed, a readout signal is detected from the location of the storage medium where the RLL-coded data is written, equalization is performed on the readout signal, and the maximum likelihood (ML) sequence detection is then performed on the readout signal. After the ML sequence detection is performed, the RLL decoding is performed, and the ECC is performed to detect an error in the decoded data signal.

During the ECC-based error detection process, if an error is detected in the decoded signal, a readout signal is detected from a defective sector of the storage medium and a given error correcting code (ECC) can recover the original data from the defective sector, provided that the number of erroneous bits is less than the maximum number allowed by that particular code. When an error is detected again in the decoded signal, it is determined that a defect exists on the storage medium. The location of the medium where the defect is detected is registered in a defect region and an alternate sector in place of the defective sector is reconstructed.

FIG. 1 shows the waveform of an input signal in a case of no defect existing on the storage medium and the waveform of an input signal in a case of a defect existing on the storage medium, in order to explain the maximum likelihood sequence detection.

In FIG. 1, the dotted line indicates the waveform of the input signal with no defect on the medium (which signal will be called the non-defect signal), while the solid line indicates the waveform of the input signal with a defect on the medium (which signal will be called the defective signal).

FIG. 2 shows the results of decoding of the input signals, which are used in the maximum likelihood sequence detection.

In the waveforms of FIG. 1, the decoded bit is set to “+1” when the amplitude of the input signal is larger than an upper threshold level “V+1”, it is set to “−1” when the amplitude of the input signal is smaller than a lower threshold level “V−1”, and it is set to “0” when the amplitude of the input signal is between the upper threshold level “V+1” and the lower threshold level “V−1”. The sequence of the decoded bits is stored in a memory.

As shown in FIG. 2, (A) indicates the results of decoding of the non-defect signal (indicated by the dotted line in FIG. 1), (B) indicates a sequence of odd-number decoded bits for the non-defect signal, and (C) indicates a sequence of even-number decoded bits for the non-defect signal. As shown in FIG. 2, (D) indicates the results of decoding of the defective signal (indicated by the solid line in FIG. 1), (E) indicates a sequence of odd-number decoded bits for the defective signal, and (F) indicates a sequence of even-number decoded bits for the defective signal.

When the defective signal has a missing portion indicated by the solid line in FIG. 1, where the amplitude of the signal is not larger than the upper threshold level V+1, the sequence of odd-number decoded bits indicated by (E) in FIG. 2 includes a zero bit “0” corresponding to the missing portion of the defective signal. However, even if the defect is detected in the sequence of the decoded bits, the defect is corrected through the error correction ability and the original data is recovered. In the case of the sequence indicated by (E) in FIG. 2, the zero bit “0” is corrected to the bit “1” that is the same as that in the sequence of the decoded bits for the non-defect signal. In this manner, the existing data storage apparatus determines that there is no error on the storage medium even if a small defect exists on the storage medium.

Accordingly, in the defect detection process of the existing data storage apparatus, it is determined as a result of the ECC, that there is no error on the storage medium even if a small defect exists on the storage medium. Since no defect is detected on the storage medium, and the defective sector where the defect actually exists on the medium is reconstructed into an alternate sector. Further, for the achievement for improved data storage capacity, the margin of the amplitude of a readout signal that can be detected by the existing data storage apparatus is reduced. The magnetization will be reduced if a defect exists on the storage medium, and the margin of the amplitude of the readout signal from the defective sector will be further reduced. Due to medium change noises, head's thermal noises or electrical noises, read/write errors are likely to take place when the defective sector of the storage medium is accessed by the existing data storage apparatus.

In such circumstances, the existing data storage apparatus may irregularly determine whether a defect exists on the storage medium, and the results of the medium defect detection will be inadequate for providing good reliability of the detection.

Further, the defect detection process of the existing data storage apparatus does not discriminate between an acquisition section and a data section in a block of binary data. It is impossible for the existing data storage apparatus to detect an error in the acquisition sections of the data frames. It is desirable to provide a defect detection method and apparatus that can accurately and reliably detect a small defect on the storage medium.

### SUMMARY OF THE INVENTION

In order to overcome the above-described problems, it is an object of the present invention to provide an improved medium defect detection method that can accurately and reliably detect a small defect on the storage medium.

Another object of the present invention is to provide a data storage apparatus using an improved medium defect detection method that can accurately and reliably detect a small defect on the storage medium.

The above-mentioned objects of the present invention are achieved by a medium defect detection method which detects a defect on a storage medium based on readout information from the medium, the method comprising the steps of: providing a data storage apparatus selectively operable for one of a normal data reading and a medium defect detection, the data storage apparatus providing an ability to correct an error in the readout information during the normal data reading; writing a sequence of data frames to the medium; reading the data frame sequence from the medium by producing a readout signal; and determining whether an error occurs in the readout signal, wherein the steps of writing, reading and determining are performed during the medium defect detection by inhibiting the error correction ability of the data storage apparatus.

The above-mentioned objects of the present invention are achieved by a data storage apparatus which records information onto a storage medium and reproduces the information from the storage medium, the data storage apparatus comprising: a read/write unit which writes a sequence of data frames to the medium and reading the sequence of data frames from the medium by producing a readout signal; a detector that is selectively operable for one of a normal data reading and a medium defect detection, the detector performing, during the normal data reading, a maximum likelihood sequence detection of the readout signal produced by the read/write unit, the sequence detection providing an ability to correct an error in the readout signal, and the detector performing, during the medium defect detection, an error detection of the readout signal; and a control unit which controls the detector to perform selected one of the sequence detection and the error detection, wherein, when the error detection is selected, the control unit reduces the error correction ability of the sequence detection of the detector to a level smaller than a level of the error correction ability when the sequence detection is selected.

The above-mentioned objects of the present invention are achieved by a data storage apparatus which records information onto a storage medium and reproduces the information from the storage medium, the data storage apparatus comprising: a read/write unit which writes a sequence of data frames to the medium and reads the sequence of data frames from the medium by producing a readout signal, each frame including a sync information and a write information, the sync information needed to read the write information of the frame from the medium; a detector that is selectively operable for one of a normal data reading and a medium defect detection, the detector performing, during the normal data reading, a maximum likelihood sequence detection of the readout signal produced by the read/write unit, the sequence detection providing an ability to correct an error in the readout signal, and the detector performing, during the medium defect detection, an error detection of the readout signal; and a control unit which controls the detector to perform selected one of the sequence detection and the error detection, wherein, when the error detection is selected, the control unit performs a write/read process for the medium with the read/write unit at least twice by using first and second data formats, the sync information of each frame, recorded on the medium in the second data format being shifted from the sync information of a corresponding frame recorded in the first data format, and matching with the write information of the corresponding frame recorded in the first data format.

In the medium defect detection method and the data storage apparatus of the present invention, a second filter coefficient selected for the filtering of a digital filter during the medium defect detection is smaller than a first filter coefficient selected during the normal data reading, and it is possible to prevent the medium defect detection ability from being excessively affected by the filtering of the digital filter. Further, in the medium defect detection method and the data storage apparatus of the present invention, a first expected value is supplied for the maximum likelihood sequence detection during the normal data reading, and a second expected value is supplied for the maximum likelihood sequence detection during the medium defect detection. The second expected value selected during the medium defect detection is smaller than the expected value selected during the normal data reading.

Therefore, the undesired error correction of the maximum likelihood sequence detection is not effective for the error correction on the data signal during the medium defect detection. The medium defect detection method and the data storage apparatus of the present invention are effective in accurately and reliably detecting a small modification of the signal waveform due to a small error on the storage medium.

### BRIEF DESCRIPTION OF THE DRAWINGS

Other objects, features and advantages of the present invention will become apparent from the following detailed description when read in conjunction with the accompanying drawings.

FIG. 1 is a diagram for explaining the waveform of an input signal with no defect on the storage medium and the waveform of an input signal with a defect on the storage medium.

FIG. 2 is a diagram for explaining the results of decoding of the input signals, which are used for a maximum likelihood detection that detects a defect on the storage medium.

FIG. 3 is a block diagram of one preferred embodiment of the data storage apparatus of the invention.

FIG. 4 is a perspective view of a magnetic disk apparatus in which the data storage apparatus of the invention is embodied.

FIG. 5 is a block diagram of an FIR filter in the data storage apparatus of the present embodiment.

FIG. 6 is a diagram for explaining the waveform of an output data signal at the output of the FIR filter.

FIG. 7 is a block diagram of a Viterbi detector in the data storage apparatus of the present embodiment.

FIG. 8A and FIG. 8B are diagrams for explaining an operation of the Viterbi detector when the expected value is changed.

FIG. 9A is a diagram for explaining the waveform of a digital data signal at the input of the Viterbi detector.

FIG. 9B is a diagram for explaining the waveform of a signal at the output of a subtracter in the Viterbi detector during the medium defect detection.

FIG. 9C is a diagram for explaining the waveform of a signal at the output of an EXOR gate in the Viterbi detector during the medium defect detection.

FIG. 9D is a diagram for explaining the waveform of a signal at the output of the EX-OR gate in the Viterbi detector during the normal data reading.

FIG. 10 is a flowchart for explaining a medium defect detection initialize process performed by the data storage apparatus of the present embodiment before starting the medium defect detection.

FIG. 11 is a flowchart for explaining a medium defect detection process performed by the data storage apparatus of the present embodiment.

FIG. 12 is a diagram for explaining an example of primary and secondary data formats of the storage medium for use in the medium defect detection process of FIG. 11.

FIG. 13 is a diagram for explaining another example of the secondary data format of the storage medium for use in the medium defect detection process of FIG. 11.

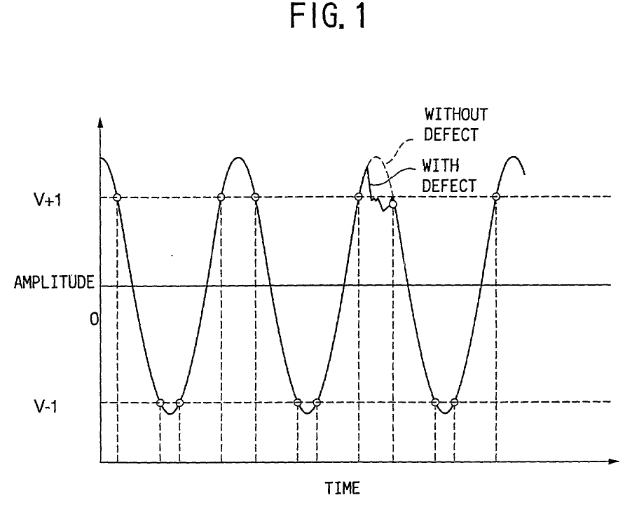

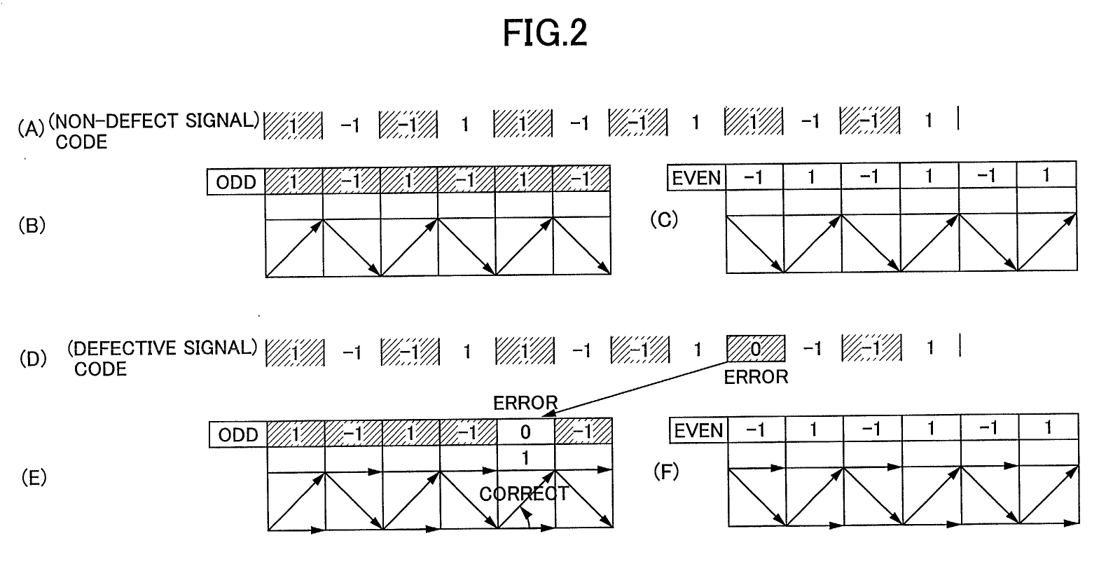

### DETAILED DESCRIPTION OF PREFERRED EMBODIMENTS

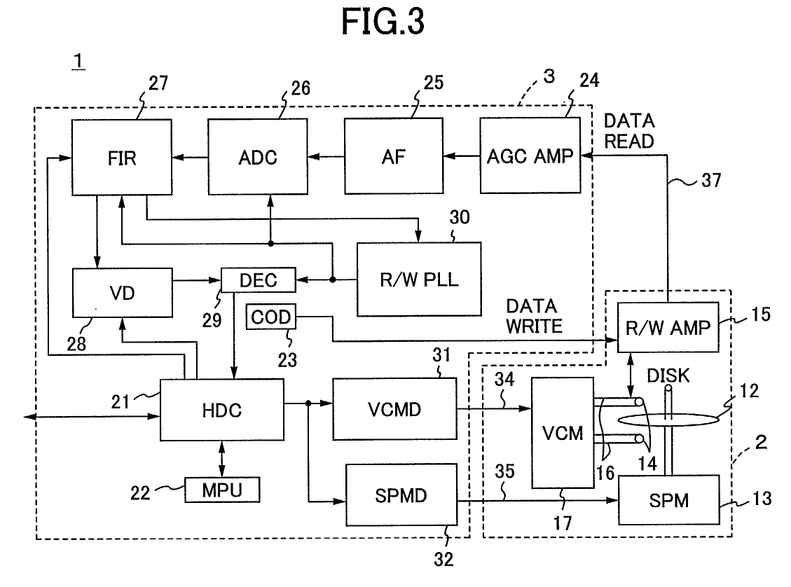

A description will now be provided of preferred embodiments of the present invention with reference to FIG. 3 through FIG. 13.

FIG. 3 shows a configuration of one preferred embodiment of the data storage apparatus of the present invention.

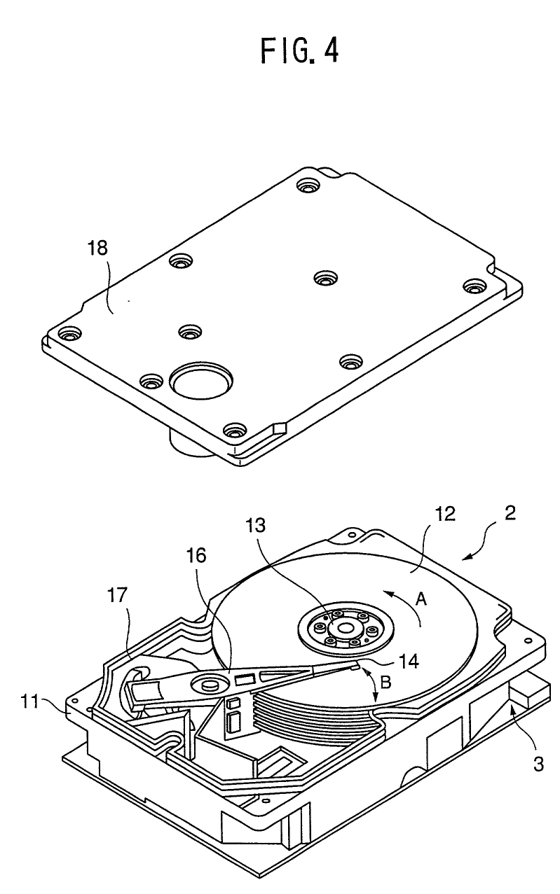

In the present embodiment, the data storage apparatus of the invention is applied to a magnetic disk drive. FIG. 4 is a perspective view of the magnetic disk apparatus in which the data storage apparatus of the invention is embodied.

As shown in FIG. 3 and FIG. 4, in the data storage apparatus 1 of the present embodiment, an enclosure 2 and an integrated circuit (IC) board 3 are provided. The enclosure 2 generally comprises a plurality of magnetic disks 12, a spindle motor (SPM) 13, a plurality of magnetic heads 14, a read/write amplifier (R/W AMP) 15, a plurality of head arms 16 and a voice coil motor (VCM) 17, which are contained in a case 11, and these elements of the case 11 are enclosed with a cover 18.

The magnetic disks 12 are rotated by the spindle motor 13 in a rotating direction indicated by the arrow A in FIG. 4. The magnetic heads 14 are placed over the top surfaces and the back surfaces of the magnetic disks 12. Each magnetic disk 12 is covered with a magnetic material for recording information. Each of the magnetic heads 14 is an electromagnet that produces magnetic fields to read or write bit streams on the track of the magnetic disk 12. The magnetic heads 14 are fixed to the head arms 16, and the head arms 16 are movably attached to the VCM 17. Each of the magnetic heads 14 residing on the head arms 16 is positioned by the VCM 17 such that the magnetic head 14 is movable in a radial direction (indicated by the arrow B in FIG. 4) of the magnetic disk 12.

As shown in FIG. 3, the SPM 13, the R/W AMP 15 and the VCM 17 are electrically connected to the integrated circuit board 3, and the operations of these elements 13, 15 and 17 are controlled by the integrated circuit board 3.

The integrated circuit (IC) board 3 generally comprises a hard disk controller (HDC) 21, a microprocessor unit (MPU) 22, an encoder (COD) 23, an automatic gain control amplifier (AGC AMP) 24, an active filter (AF) 25, an analog-to-digital converter (ADC) 26, a finite impulse response (FIR) filter 27, a Viterbi detector (VD) 28, a decoder (DEC) 29, a read/write phase-locked loop (R/W PLL) circuit 30, a voice coil motor driver (VCMD) 31, and a spindle motor driver (SPMD) 32.

The VCMD 31 of the IC board 3 is connected to the VCM 17 of the enclosure 2 through a line 34, and the SPMD 32 of the IC board 3 is connected to the SPM 13 of the enclosure 2 through a line 35. The encoder 23 of the IC board 3 is connected to the R/W AMP 15 of the enclosure 2 via a data writing line 36, and the R/W AMP 15 of the enclosure 2 is connected to the AGC AMP 24 of the IC board 3 through a data reading line 37.

When writing data to the magnetic disk 12, the information to be written (called the write information) is transmitted from a host computer (not shown) through the HDC 21 to the MPU 22. The HDC 21 controls the entire magnetic disk apparatus under the control of the MPU 22. The MPU 22 performs the scrambling of the received write information, and adds parity bits to a sequence of binary data of the write information in order for the error correction coding. The encoder 23 performs the runlength-limited (RLL) coding of the resulting write information, and the RLL-coded data is transmitted from the encoder 23 to the R/W AMP 15 of the enclosure 2 through the data writing line 36.

In the enclosure 2, the R/W AMP 15 amplifies the write data signal, received from the encoder 23, and supplies the amplified signal to the magnetic heads 14. In the magnetic heads 14, the write head, which includes an inductance head, is driven in accordance with the amplified signal received from the R/W AMP 15. The inductance head of the write head produces magnetic fields to write the bit streams to the track of the magnetic disk 12. Hence, the write information is recorded onto the magnetic disk 12.

When reading data from the magnetic disk 12, the resistance of a magneto-resistive (MR) element in the magnetic head 14 is changed in accordance with a pattern of magnetization of the magnetic disk 12. A readout signal is produced at the magnetic head 14 in accordance with the change of the resistance, and the readout signal from the magnetic head 14 is amplified at the R/W AMP 15. The amplified readout signal is transmitted from the R/W AMP 15 to the AGC amplifier 24 of the IC board 3 through the data reading line 37.

In the IC board 3, the AGC amplifier 24 controls the amplification ratio so that the maximum amplitude of the readout signal is set at a constant level. The readout signal, after the amplification ratio control, is transmitted from the AGC amplifier 24 to the active filter 25. The active filter 25 removes the undesired components in the readout signal received from the AGC amplifier 24. The resulting readout signal is transmitted from the active filter to the ADC 26.

The ADC 26 converts the readout signal, received from the active filter 25, into a digital data signal (or a sequence of samples). The digital data signal is transmitted from the ADC 26 to the FIR filter 27. The HDC 21 controls the FIR filter 27 to perform selective filtering on the digital data signal received from the ADC 26, which depends on whether the normal data reading or the medium defect detection is currently performed.

In the data storage apparatus 1 of FIG. 3, the sequence of samples, which is supplied to the FIR filter 27 by the ADC 26, is also transmitted to the R/W PLL circuit 30. The R/W PLL circuit 30 generates a clock signal (also called a local clock) in response to the sequence of samples that is received from the ADC 26 via the FIR filter 27. The R/W PLL circuit 30 supplies the clock signal to each of the ADC 26, the FIR filter 27, the decoder 29 and the encoder 23. These elements 26, 27, 29 and 23 of the data storage apparatus 1 operate on the received signal in synchronization with the clock signal supplied by the R/W PLL circuit 30.

The medium defect detection method and the data storage apparatus of the present invention are characterized by performing the selective filtering of the FIR filter 27. Under the control of the MPU 22, at a start of the medium defect detection, the HDC 21 selects second filter coefficients of the FIR filter 27 that are different from first filter coefficients of the FIR filter 27 selected during the normal data reading.

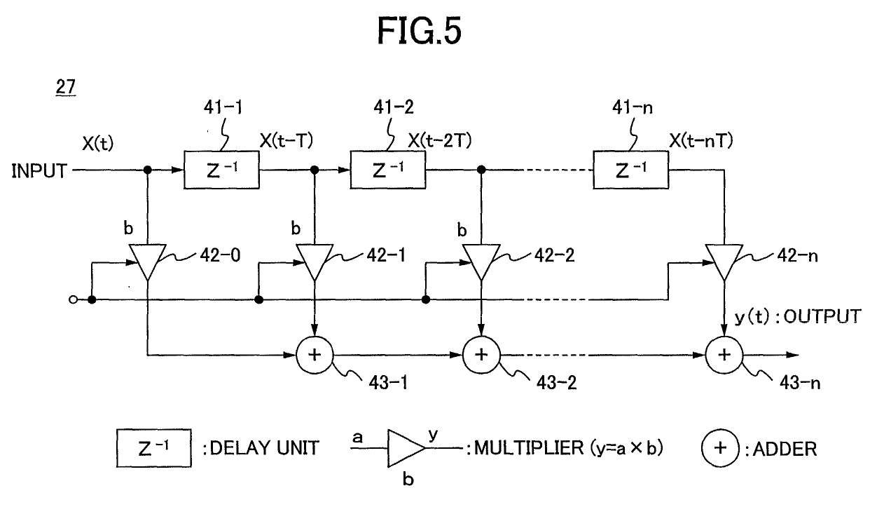

FIG. 5 shows a configuration of the FIR filter 27 in the data storage apparatus of the present embodiment.

As shown in FIG. 5, in the FIR filter 27, a plurality of delay units 41-1, 41-2, . . . , 41-n, a plurality of multipliers 42-0, 42-1, . . . , 42-n, and a plurality of adders 43-1, 43-2, . . . , 43-n are provided. The delay units 41-1 through 41-n are cascaded with the digital data signal X(t) (supplied from the ADC 26) being input to the delay unit 41-1. The input data signal X(t) is delayed by the respective delay units 41-1 through 41-n by the sampling duration T. For example, the delayed data signal at the output of the delay unit 41-1 is represented by “X(t−T)”, and the delayed data signal at the output of the delay unit 41-2 is represented by “X(t−2T)”.

In the FIR filter 27 of FIG. 5, the multiplier 42-0 produces a multiplication of the input data signal “X(t)” and the filter coefficient “b”, and supplies the product “bX(t)” to the adder 43-1. The i-th multiplier of the multipliers 42-1 through 42-n produces a multiplication of the i-th delayed data signal “X(t−iT)”, at the output of the i-th delay unit 41-i, and the filter coefficient “b”, and supplies the product “bX(t−iT)” to the i-th adder of the adders 43-1 through 43-n.

The MPU 22 controls the HDC 21 such that the HDS 21 selects one of the first filter coefficients “bo” and the second filter coefficients “bs” in the FIR filter 27, which depends on whether the normal data reading or the medium defect detection is currently performed. Specifically, during the medium defect detection, the HDC 21 selects the second filter coefficients “bs” of the FIR filter 27 that are smaller than the first filter coefficients “bo” of the FIR filter 27 selected during the normal data reading.

In the FIR filter 27 of FIG. 5, the adder 43-1 produces a sum of the product “bX(t)” output from the multiplier 42-0 and the product “bX(t−T)” output from the multiplier 42-1, and supplies the sum to the adder 43-2. The i-th adder of the adders 43-1 through 43-n produces a sum of the product “bX(t)+bX(t−T)+ . . . +bX(t−(i−1)T)” output from the (i−1)-th multiplier 42-(i−1) and the product “bX(t−iT)” output from the i-th multiplier 42-i. Hence, the FIR filter 27 supplies the data signal y(t), output from the adder 43-n, to the Viterbi detector 28 where y(t) is indicated by the formula: y(t)=bX(t)+bX(t−T)+ . . . +bX(t−nT).

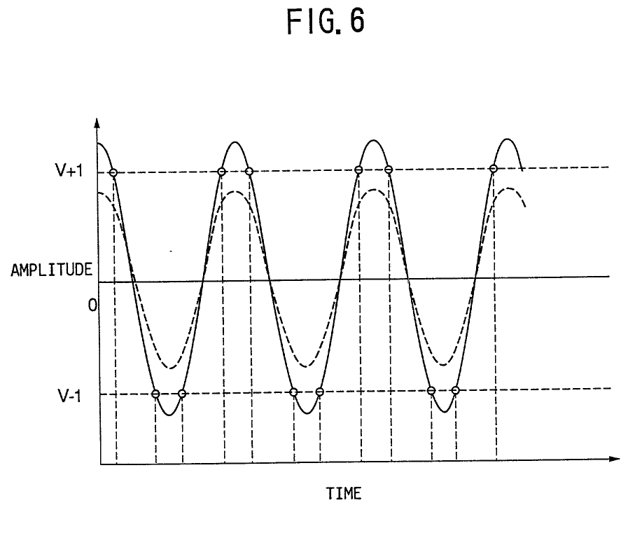

FIG. 6 shows the waveform of an output data signal at the output of the FIR filter 27 in the data storage apparatus of the present embodiment.

In FIG. 6, the solid line indicates the waveform of the output data signal of the FIR filter 27 wherein the first filter coefficients “bo” are selected during the normal data reading, while the dotted line indicates the waveform of the output data signal of the FIR filter 27 wherein the second filter coefficients “bs” are selected during the medium defect detection.

As shown in FIG. 6, during the medium defect detection, the second filter coefficients “bs” that are smaller than the first filter coefficients “bo” are selected for the FIR filter 27, and the amplitude of the data signal at the output of the FIR filter 27 is reduced so as to fall within the range between the upper threshold level “V+1” and the lower threshold level “V−1” as in the waveform indicated by the dotted line. Therefore, it is possible to prevent the medium defect detection from being excessively affected by the filtering of the FIR filter 27. The undesired error correction of the ML sequence detection of the Viterbi detector 28 is not effective for the error correction on the data signal output from the FIR filter 27. A small modification of the signal waveform due to a small error on the storage medium can be retained in the data signal output from the FIR filter 27.

Referring back to FIG. 3, in the data storage apparatus 1 of the present embodiment, when reading the data from the storage medium 12, the data signal, after the selective filtering is performed at the FIR filter 27, is transmitted to the Viterbi detector 28. In the present embodiment, the Viterbi detector 28 performs, during the normal data reading, the maximum likelihood (ML) sequence detection of the data signal, output from the FIR filter 27, based on the Viterbi algorithm. During the medium defect detection, the Viterbi detector 28 performs a threshold-based error detection of the data signal output from the FIR filter 27, instead of the ML sequence detection, which will be described later.

In the data storage apparatus 1 of FIG. 3, the data signal output from the Viterbi detector 28 is transmitted to the decoder 29. The decoder 29 performs the decoding of the data signal supplied by the Viterbi detector 28, and transmits the decoded data signal through the HDC 21 to the MPU 22. The MPU 22 performs the error checking based on the ECC of the decoded data signal received from the decoder 29. If an error in the decoded data signal is detected, the original data is recovered. When no error in the decoded data signal is detected as the result of the ECC, the MPU 22 performs the descrambling of the decoded data signal so that the original data is reconstructed. The reconstructed data signal is transmitted from the MPU 22 to the host computer (not shown) via the HDC 21.

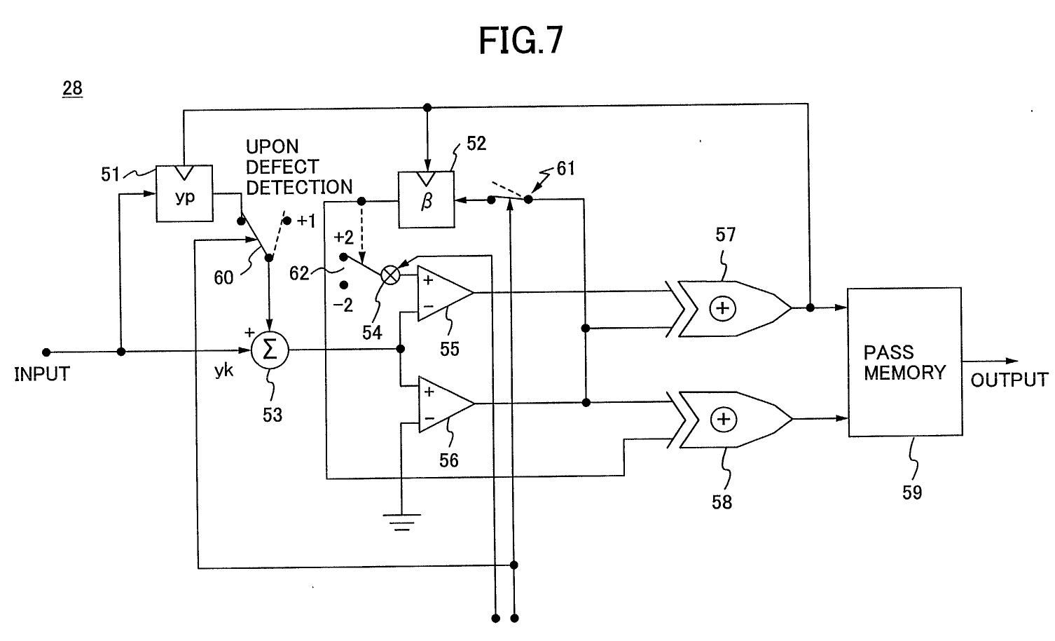

Next, FIG. 7 shows a configuration of the Viterbi detector 28 in the data storage apparatus of the present embodiment.

As shown in FIG. 7, in the Viterbi detector 28 of the present embodiment, a hold circuit 51, a hold circuit 52, a subtracter 53, a multiplier 54, a comparator 55, a comparator 56, an exclusive-OR gate 57, an exclusive-OR gate 58, a pass memory 59, and a set of switches 60, 61 and 62 are provided.

In the Viterbi detector 28 of FIG. 7, the hold circuit 51 holds the peak value (yp) of the input data signal (supplied by the FIR filter 27) in response to an output digital signal of the exclusive-OR gate 57. An output digital signal of the hold circuit 51 is transmitted through the switch 60 to the subtracter 53. The subtracter 53 subtracts the peak value (yp) from the input data signal.

The digital signal output from the subtracter 53 is transmitted to both the inverting input of the comparator 55 and the non-inverting input of the comparator 56. A controlled value that is selected at the switch 62 between the value +2 and the value −2 is transmitted through the multiplier 54 to the non-inverting input of the comparator 55. The multiplier 54 produces a threshold value as a result of multiplication of the controlled value from the switch 62 and a coefficient of the multiplier 54, and the threshold value is transmitted from the multiplier 54 to the non-inverting input of the comparator 55. The inverting input of the comparator 56 is grounded.

The comparator 55 compares the result of the subtraction, output from the subtracter 53, with the threshold value. When the output of the subtracter 53 is larger than the threshold value, the comparator 55 outputs the low-level signal (or the value 0) to the exclusive-OR gate 57. When the output of the subtracter 53 is less than the threshold value, the comparator 55 outputs the high-level signal (or the value 1) to the exclusive-OR gate 57.

The comparator 56 compares the result of the subtraction, output from the subtracter 53, with the grounding level. When the output of the subtracter 53 is larger than the grounding level, the comparator 56 outputs the high-level signal (or the value 1) to the exclusive-OR gate 58. When the output of the subtracter 53 is less than the grounding level, the comparator 56 outputs the low-level signal (or the value 0) to the exclusive-OR gate 58. Further, an output signal of the comparator 56 is transmitted through the switch 61 to the hold circuit 52.

The exclusive-OR gate 57 provides a logic comparison of an output signal of the comparator 55 and an output signal of the comparator 56. Typically, the exclusive-OR gate 57 produces an output 1 only when one single input is equal to 1, otherwise the exclusive-OR gate 57 produces an output 0. The result of the logic comparison output from the exclusive-OR gate 57 is stored in the pass memory 59, and it is transmitted to both the hold circuit 51 and the hold circuit 52.

The hold circuit 52 holds the result (β) of the comparison (output from the comparator 56) in response to an output digital signal of the exclusive-OR gate 57. An output digital signal of the hold circuit 52 is transmitted to both the switch 62 and the input of the exclusive-OR gate 58.

The exclusive-OR gate 58 provides a logic comparison of an output signal of the comparator 56 and an output signal of the hold circuit 52. Typically, the exclusive-OR gate 58 produces an output 1 only when one single input is equal to 1, otherwise the exclusive-OR gate 58 produces an output 0. The result of the logic comparison output from the exclusive-OR gate 58 is stored in the pass memory 59.

In the Viterbi detector 28 of FIG. 7, the switch 60 is set in one of a first position (indicated by the solid line in FIG. 7) and a second position (indicated by the dotted line in FIG. 7) in response to a switch control signal supplied from the MPU 22. During the normal data reading mode of the data storage apparatus 1, the switch 60 is set in the first position by the control signal of the MPU 22, so that the peak value (yp) of the input data signal held by the hold circuit 51 is transmitted through the switch 60 to the subtracter 53. During the medium defect detection mode of the data storage apparatus 1, the switch 60 is set in the second position by the control signal of the MPU 22, so that a fixed value “+1” is transmitted to the subtracter 53. Namely, during the medium defect detection, the amplitude of the input data signal (supplied from the FIR filter 27) is compared with the threshold value without subtraction of the peak value (yp) from the input data signal.

In the Viterbi detector 28 of FIG. 7, the switch 61 is set in one of a first position (indicated by the solid line in FIG. 7) and a second position (indicated by the dotted line in FIG. 7) in response to the switch control signal supplied from the MPU 22. During the normal data reading mode of the data storage apparatus 1, the switch 61 is set in the first position by the control signal of the MPU 22, so that the output signal of the comparator 56 is transmitted through the switch 61 to the hold circuit 52. During the medium defect detection mode of the data storage apparatus 1, the switch 61 is set in the second position by the control signal of the MPU 22, so that the connection of the output of the comparator 56 and the input of the hold circuit 52 is cut off by the switch 61.

Further, in the Viterbi detector 28 of FIG. 7, during the normal data reading, the switch 62 is set in one of a first position (the value +2) and a second position (the value −2) in response to the output signal of the hold circuit 52 (or the result β of the comparison at the comparator 56). Specifically, when the output-of the exclusive-OR gate 57 is at the high level (equal to 1), the switch 62 is set in the first position and the value +2 is transmitted from the switch 62 to the multiplier 54. When the output of the exclusive-OR gate 57 is at the low level (equal to 0), the switch 62 is set in the second position and the value −2 is transmitted to the multiplier 54. On the other hand, during the medium defect detection, the switch 62 is fixed to the second position and the value −2 is always transmitted to the multiplier 54.

Further, in the Viterbi detector 28 of FIG. 7, a selected one of a first coefficient and a second coefficient is supplied from the MPU 22 to the multiplier 54. As described above, the multiplier 54 produces the threshold value as a result of multiplication of the controlled value from the switch 62 and the selected coefficient received at the multiplier 54, and the threshold value is transmitted from the multiplier 54 to the noninverting input of the comparator 55. Specifically, in the present embodiment, the first coefficient that is equal to 1 is supplied from the MPU 22 to the multiplier 54 during the normal data reading, and the second coefficient that is larger than 1 is supplied from the MPU 22 to the multiplier 54 during the medium defect detection.

According to the medium defect detection method of the present embodiment, the selected one of the first coefficient and the second coefficient is supplied from the MPU 22 to the multiplier 54, and the expected value, which is supplied to the Viterbi detector 28 during the medium defect detection, is smaller than the expected value supplied to the Viterbi detector 28 during the normal data reading. The undesired error correction of the ML sequence detection of the Viterbi detector 28 is not effective for the error correction on the data signal output from the FIR filter 27 during the medium defect detection. Therefore, the medium defect detection method and the data storage apparatus of the present embodiment are effective in accurately and reliably detecting a small modification of the signal waveform due to a small error on the storage medium.

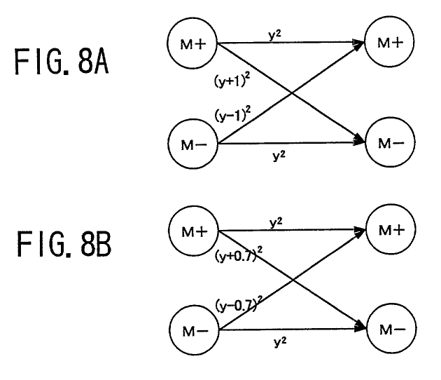

FIG. 8A and FIG. 8B show an operation of the Viterbi detector 28 when the expected value is changed.

FIG. 8A shows a state transition of the ML sequence detection of the Viterbi detector 28 when the expected value selected during the normal data reading is supplied to the Viterbi detector 28. FIG. 8B shows a state transition of the ML sequence detection of the Viterbi detector 28 when the expected value that is smaller than that of the normal data reading is supplied to the Viterbi detector 28 during the medium defect detection.

In the present embodiment, it is assumed that the expected value during the normal data reading is set to 1 and the expected value during the medium defect detection is set to 0.7, and that the Viterbi detector 28 performs the ML sequence detection in both the normal data reading case and the medium defect detection case.

As shown in FIG. 8A, during the normal data reading, the expected value of a transition from the state M+ to the state M+ and the expected value of a transition from the state M− to the state M− are indicated by y². The expected value of a transition from the state M+ to the state M− is indicated by (y+1)². The expected value of a transition from the state M− to the state M+ is indicated by (y−1)^{2.}

As shown in FIG. 8B, during the medium defect detection, the expected value of a transition from the state M+ to the state M+ and the expected value of a transition from the state M− to the state M− are indicated by y². The expected value of a transition from the state M+ to the state M− is indicated by (y+0.7)². The expected value of a transition from the state M− to the state M+ is indicated by (y−0.7)².

In the above-described embodiment, the expected value, which is supplied to the Viterbi detector 28 during the medium defect detection, is smaller than the expected value supplied to the Viterbi detector 28 during the normal data reading. The undesired error correction of the ML sequence detection of the Viterbi detector 28 is not so effective for the error correction on the data signal output from the FIR filter 27 during the medium defect detection. Therefore, the medium defect detection method and the data storage apparatus of the present embodiment are effective in accurately and reliably detecting a modification of the signal waveform due to a small error on the storage medium.

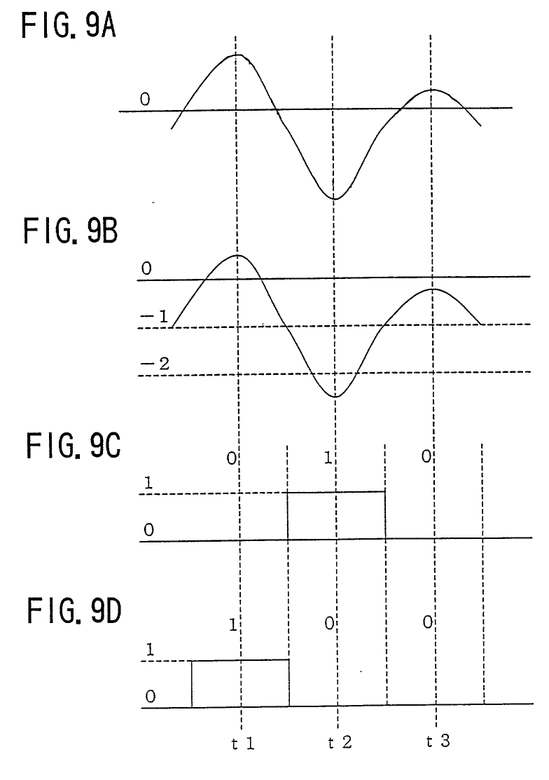

Next, a description will be given of an operation of the Viterbi detector 28 during the medium defect detection with reference to FIG. 9A through FIG. 9D.

FIG. 9A shows the waveform of a digital data signal at the input of the Viterbi detector 28. FIG. 9B shows the waveform of a signal at the output of the subtracter 53 in the Viterbi detector 28 during the medium defect detection.

When the data signal shown in FIG. 9A is transmitted to the Viterbi detector 28 during the medium defect detection, the signal level is changed by the subtracter 53 as shown in FIG. 9B. The DC bias component of the input data signal is set to the level “−1”. The data signal shown in FIG. 9B is transmitted to both the comparator 55 and the comparator 56. The comparator 55 compares the amplitude of the data signal (shown in FIG. 9B) with the threshold value “−2”. When the signal level is larger than the threshold value “−2”, the comparator 55 outputs the low-level signal (or the value 0) to the exclusive-OR gate 57. When the signal level is less than the threshold value “−2”, the comparator 55 outputs the high-level signal (or the value 1) to the exclusive-OR gate 57.

FIG. 9C shows the waveform of a signal at the output of the exclusive-OR gate 57 in the Viterbi detector 28 during the medium defect detection. As shown in FIG. 9C, the output of the exclusive-OR gate 57, at the sampling instant “t2” that the signal level is less than the threshold value “−2”, is set to 1, and the output of the exclusive-OR gate 57, at the sampling instants “t1” and “t3” that the signal level is larger than the threshold value “−2”, is set to 0.

FIG. 9D shows the waveform of a signal at the output of the EX-OR gate 57 in the Viterbi detector 28 during the normal data reading. As shown in FIG. 9D, during the normal data reading, the output of the exclusive-OR gate 57, at the sampling instant “t1” that the signal level is larger than the threshold value “0”, is set to 1, and the output of the exclusive-OR gate 57, at the sampling instants “t2” and “t3” that the signal level is less than the threshold value “0”, is set to 0.

The results of the detection shown in the waveforms of FIG. 9C and FIG. 9D are stored in the pass memory 59.

As in the waveform of FIG. 9C, during the medium defect detection, the DC bias component of the input data signal is set to the level “−1” and the threshold value supplied to the comparator 55 is fixed to “−2”. The undesired error correction of the ML sequence detection of the Viterbi detector 28 is invalid for the error correction on the data signal output from the FIR filter 27 during the medium defect detection. Therefore, the medium defect detection method and the data storage apparatus of the present embodiment are effective in accurately and reliably detecting a modification of the signal waveform due to a small error on the storage medium.

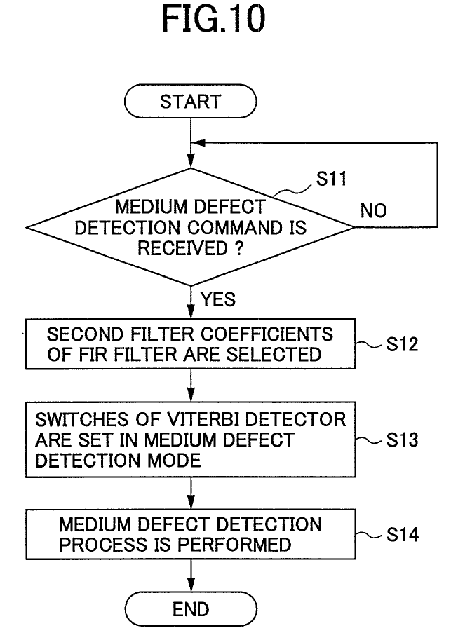

Next, FIG. 10 shows a medium defect detection initialize process that is performed by the MPU 22 of the data storage apparatus of the present embodiment before starting the medium defect detection.

As shown in FIG. 10, the MPU 22 at step S11 determines whether a medium defect detection command is received from the host computer (not shown) or others. When the result at the step S11 is negative, the control of the MPU 22 is transferred to the step S11, and the step S11 is repeated.

When the result at the step S11 is affirmative, the MPU 22 at step S12 controls the HDC 21 so that the HDC 21 selects the second filter coefficients “bs” of the FIR filter 27 for use in the medium defect detection. As described above, the second filter coefficients “bs” are selected for the FIR filter 27 at a start of the medium defect detection, and the second filter coefficients “bs” selected during the medium defect detection are smaller than the first filter coefficients “bo” selected during the normal data reading.

According to the medium defect detection method of the present embodiment, it is possible to prevent the medium defect detection ability from being excessively affected by the filtering of the FIR filter 27. The undesired error correction of the ML sequence detection of the Viterbi detector 28 is not effective for the error correction on the data signal output from the FIR filter 27 during the medium defect detection. A small modification of the signal waveform due to a small error on the storage medium can be retained in the data signal output from the FIR filter 27.

After the step S12 is performed, the MPU 22 at step S13 controls the setting of the switches 60-62 of the Viterbi detector 28 such that the switches 60-62 are set in the medium defect detection mode. As the switches 60-62 are set in the medium defect detection mode, the fixed value “+1” is supplied to the subtracter 53 via the switch 60, the connection of the hold circuit 52 and the comparator 56 is cut off at the switch 61, and the fixed threshold value “−2” is supplied to the comparator 55 via the switch 62.

After the step S13 is performed, the MPU 22 at step S14 controls the HDC 21 so that the medium defect detection process is performed, which will be described below. By shifting the acquisition and data sections of the data frames during the medium defect detection process at the step S14, the medium defect detection method and the data storage apparatus of the present embodiment are able to accurately and reliably detect an error in the acquisition sections of the data frames.

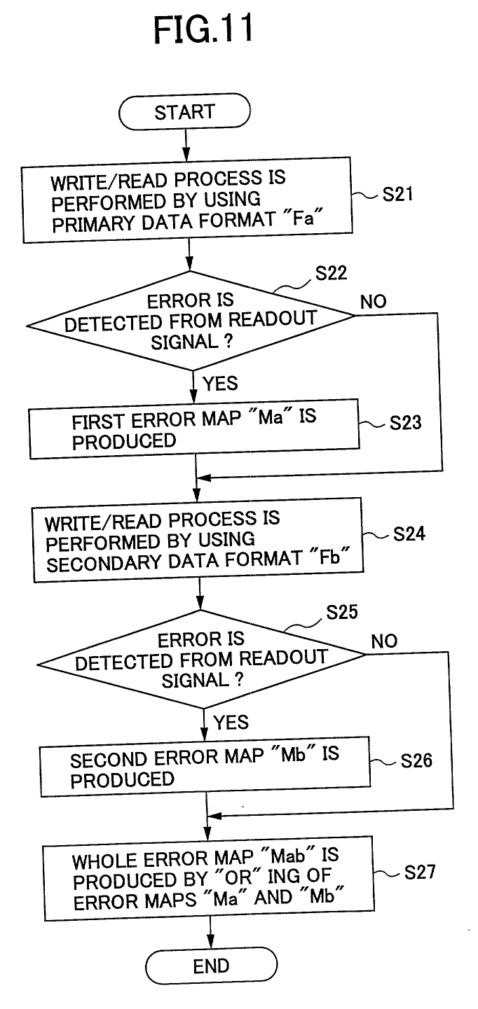

FIG. 11 shows a medium defect detection process that is performed by the MPU 22 of the data storage apparatus of the present embodiment.

The MPU 22 controls the HDC 21 so that the medium defect detection process of the present embodiment is performed in the data storage apparatus. The medium defect detection process of FIG. 11 corresponds to the step S14 of the medium defect detection initialize process of FIG. 10, and the execution of the medium defect detection process is started at the step S14 in the initialize process.

As shown in FIG. 11, the MPU 22 at step S21 performs a write/read process on the storage medium 12 in the data storage apparatus 1 by using a primary data format Fa. The primary data format Fa is a data format that is used by the data storage apparatus 1 during the normal data writing. Specifically, in the write/read process of the step S21, a sequence of data frames containing a write information is recorded onto the storage medium 12 by using the primary data format Fa, and a readout signal is produced from the location of the storage medium 12 where the write information is written.

After the step S21 is performed, the MPU 22 at step S22 determines whether an error occurs in the readout signal obtained at the step S21. When the result at the step S22 is affirmative (the occurrence of an error), the MPU 22 at step S23 produces a first error map Ma related to the primary data format Fa, and temporarily stores the first error map Ma. In the first error map Ma, the address of each defective sector, the length of the data recorded in the primary data format Fa, the address of the alternate sector for each defective sector, and other items are contained.

On the other hand, when the result at the step S22 is negative, the control of the MPU 22 is transferred to step S24 and the MPU 22 does not perform the step S23.

After the step S23 is performed, the MPU 22 at step S24 performs a write/read process on the storage medium 12 in the data storage apparatus 1 by using a secondary data format Fb. The secondary data format Fb is a data format in which the acquisition and data sections of the data frames on the storage medium 12 are shifted from those of the primary data format Fa used at the step S21. Specifically, in the write/read process of the step S24, the sequence of data frames containing the write information is recorded onto the storage medium 12 by using the secondary data format Fb, and a readout signal is produced from the location of the storage medium 12 where the write information is recorded.

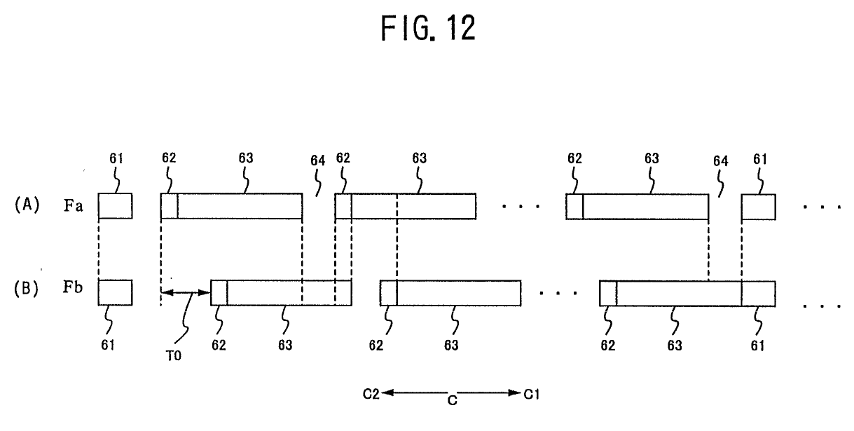

FIG. 12 shows an example of the primary and secondary data formats of the storage medium for use in the medium defect detection process of FIG. 11.

In FIG. 12, an example of the primary data format Fa is indicated by (A) and an example of the secondary data format Fb is indicated by (B).

As shown in FIG. 12, in each of the primary and secondary data formats Fa and Fb, a sequence of data frames is recorded on the storage medium, each frame including a frame identifier section 61, an acquisition section 62 and a data section 63, and two successive frames are separated by a gap 64. In the secondary data format Fb indicated by (B) in FIG. 12, the acquisition section 62 and the data section 63 are shifted from those of the primary data format Fa indicated by (A) in FIG. 12 by a time duration “TO”. In the frame identifier section 61, an identification information of that frame is recorded. In the acquisition section 62, a synchronization information needed to read out the data of that frame is recorded. In the data section 63, the write information of that frame is recorded.

As shown in the example of FIG. 12, the acquisition section 62 and the data section 63 of the secondary data format Fb are shifted from those of the primary data format Fa by the duration “TO” in a direction indicated by the arrow “C1” in FIG. 12. The position of the data section 63 of the secondary data format Fb is overlapped to the position of the acquisition section 62 of the following frame of the primary data format Fa (or to the position of the gap between the two successive frames). By detecting an error in a corresponding portion of the readout signal for the data section 63 of the secondary data format Fb, it is possible that the medium defect detection method and the data storage apparatus of the present embodiment accurately and reliably detect an error in the acquisition section 62 of the primary data format Fa, which is recorded onto the storage medium 12.

In the above example of FIG. 12, the acquisition section 62 and the data section 63 of the secondary data format Fb are shifted from those of the primary data format Fa by the duration “TO” in the direction indicated by the arrow “C1” in FIG. 12. Alternatively, the acquisition section 62 and the data section 63 of the secondary data format Fb may be shifted from those of the primary data format Fa by the duration “TO” in the opposite direction indicated by the arrow “C2” in FIG. 12. According to such alternative embodiment, it is possible that the medium defect detection method and the data storage apparatus of the present invention accurately and reliably detect an error in the acquisition section 62 of the head-end data frame that is recorded in the primary data format Fa.

Referring back to the process of FIG. 11, after the step S24 is performed, the MPU 22 at step S25 determines whether an error occurs in the readout signal obtained at the step S24. When the result at the step S25 is affirmative (the occurrence of an error), the MPU 22 at step S26 produces a second error map Mb related to the secondary data format Fb, and temporarily stores the second error map Mb. In the second error map Mb, the address of each defective sector, the length of the data recorded in the secondary data format Fb, the address of the alternate sector for each defective sector, and other items are contained.

On the other hand, when the result at the step S25 is negative, the control of the MPU 22 is transferred to step S27 and the MPU 22 does not perform the step S26.

After the step S26 is performed, the MPU 22 at step S27 produces a whole error map Mab by “OR”ing of the first error map Ma obtained at the step S23 and the second error map Mb obtained at the step S26, and stores the whole error map Mab into the storage medium 12. After the step S27 is performed, the medium defect detection process of FIG. 11 ends.

According to the medium defect detection method and apparatus of the above-described embodiment, it is possible to reliably and accurately detect a small defect on the storage medium 12, even when an error exists in the acquisition section 62 of the data frames on the storage medium 12.

In the above-described embodiment, the position of the data section 63 of the secondary data format Fb is overlapped to the position of the acquisition section 62 of the following frame of the primary data format Fa, and the medium defect detection process detects, at the step S25, an error in a corresponding portion of the readout signal for the data section 63 of the secondary data format Fb. Alternatively, the acquisition sections of the data frames on the storage medium may be configured in a dual-sink format, and an error in the acquisition section of the data frames on the storage medium may be detected depending on whether the synchronization of such acquisition sections on the storage medium is detected.

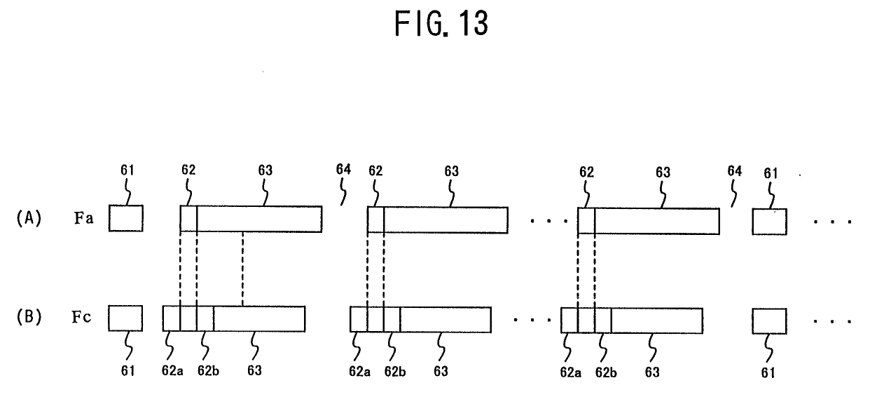

FIG. 13 shows another example of the secondary data format of the storage medium for use in the medium defect detection process of FIG. 11.

In FIG. 13, the elements which are essentially the same as corresponding elements in FIG. 12 are designated by the same reference numerals, and a description thereof will be omitted. The primary data format Fa, indicated by (A) in FIG. 13, is the same as that of FIG. 12, and the secondary data format Fc, indicated by (B) in FIG. 13 is an alternative example of the secondary data format.

In the secondary data format Fc indicated by (B) in FIG. 13, the acquisition sections 62 of the data frames are configured in a dual-sink format, a first acquisition section 62a and a second acquisition section 62b are added to the head end and the tail end of each acquisition section 62. In such alternative embodiment, an error in the acquisition sections of the data frames on the storage medium is detected depending on whether the synchronization of such acquisition sections on the storage medium is detected.

When the medium defect detection is performed in the data storage apparatus 1 of FIG. 3, the MPU 22 detects a synchronization error of the acquisition sections 62a and 62b, and monitors the clock signal produced by the R/W PLL circuit 30. When the clock signal produced by the R/W PLL circuit 30 is not out of synchronization, the MPU 22 determines that the result of the synchronization detection is effective.

In the above-described embodiment, the data storage apparatus of the present invention is applied to a magnetic disk drive. However, it is readily understood that the data storage apparatus of the present invention is applicable to other disk drives in which the alternation process is performed.

The present invention is not limited to the above-described embodiments, and variations and modifications may be made without departing from the scope of the present invention.

Further, the present invention is based on Japanese priority application No. 2000-169437, filed on Jun. 6, 2000, the entire contents of which are hereby incorporated by reference.

What is claimed is:

1. A medium defect detection method which detects a defect on a storage medium based on readout information from the medium, comprising the steps of:
providing a data storage apparatus selectively operable for one of a normal data reading and a medium defect detection, the data storage apparatus providing an ability to correct an error in the readout information during the normal data reading;
writing a sequence of data frames to the medium;
reading the data frame sequence from the medium by producing a readout signal; and
determining whether an error occurs in the readout signal, wherein said steps of writing, reading and determining are performed during the medium defect detection by inhibiting the error correction ability of the data storage apparatus.

2. A data storage apparatus which records information onto a storage medium and reproduces the information from the storage medium, comprising:
a read/write unit writing a sequence of data frames to the medium and reading the sequence of data frames from the medium by producing a readout signal;
a detector that is selectively operable for one of a normal data reading and a medium defect detection, the detector performing, during the normal data reading, a maximum likelihood sequence detection of the readout signal produced by the read/write unit, the sequence detection providing an ability to correct an error in the readout signal, and the detector performing, during the medium defect detection, an error detection of the readout signal; and
a control unit controlling the detector to perform selected one of the sequence detection and the error detection, wherein, when the error detection is selected, the control unit reduces the error correction ability of the sequence detection of the detector to a level smaller than a level of the error correction ability when the sequence detection is selected.

3. The data storage apparatus of claim 2, further comprising a digital filter performing a filtering of the readout signal produced by the read/out unit and supplying the readout signal, after the filtering is performed, to the detector, wherein a second filter coefficient, selected for the filtering of the digital filter during the medium defect detection, is smaller than a first filter coefficient selected during the normal data reading, in order to prevent the error detection of the detector from being excessively affected by the filtering of the digital filter.

4. The data storage apparatus of claim 2 wherein the control unit supplies a first expected value to the detector for the sequence detection during the normal data reading, and supplies a second expected value to the detector during the medium defect detection, the second expected value being smaller than the first expected value selected during the normal data reading.

5. A data storage apparatus which records information onto a storage medium and reproduces the information from the storage medium, comprising:
a read/write unit writing a sequence of data frames to the medium and reading the sequence of data frames from the medium by producing a readout signal, each frame including a sync information and a write information, the sync information needed to read the write information of the frame from the medium;
a detector that is selectively operable for one of a normal data reading and a medium defect detection, the detector performing, during the normal data reading, a maximum likelihood sequence detection of the readout signal produced by the read/write unit, the sequence detection providing an ability to correct an error in the readout signal, and the detector performing, during the medium defect detection, an error detection of the readout signal; and
a control unit controlling the detector to perform selected one of the sequence detection and the error detection, wherein, when the error detection is selected, the control unit performs a write/read process for the medium with the read/write unit at least twice by using first and second data formats, the sync information of each frame, recorded on the medium in the second data format being shifted from the sync information of a corresponding frame recorded in the first data format, and matching with the write information of the corresponding frame recorded in the first data format.
